(19) United States
(12) Patent Application Publication
(10) Pub. No.: US 2010/0084013 A1
(43) Pub. Date: Apr. 8, 2010

(54) SOLAR CELL

(76) Inventors: Youngjoo EO, Seoul (KR); Sehwon Ahn, Seoul (KR); Heonmin Lee, Seoul (KR); Jihoon Ko, Seoul (KR); Sunho Kim, Seoul (KR); Kwangsun Ji, Seoul (KR)

Correspondence Address: BIRCH STEWART KOLASCH & BIRCH, PO BOX 747, FALLS CHURCH, VA, 22040-0747, US

(21) Appl. No.: 12/573,671

(22) Filed: Oct. 5, 2009

(30) Foreign Application Priority Data
Oct. 6, 2008 (KR) 10-2008-0097613

(51) Int. Cl. H01L 31/00

(52) U.S. Cl. 136/255; 136/258

(57) ABSTRACT

A solar cell is disclosed. The solar cell includes an n-type or p-type amorphous silicon layer, a transparent electrode, and a metal buffer layer between the transparent electrode and the amorphous silicon layer. The metal buffer layer contains at least one of In, Sn, B, Al, Ga, and Zn. When the transparent electrode contains indium tin oxide (ITO), the metal buffer layer contains at least one of In and Sn. When the transparent electrode contains zinc oxide, the metal buffer layer contains at least one of B, Al, Ga, and Zn.

This application claims the benefit of Korean Patent Application No. ______ filed on ______, the entire contents of which is incorporated herein by reference for all purposes as if fully set forth herein.

### BACKGROUND OF THE INVENTION

1. Field of the Invention

Embodiments of the invention relate to a solar cell.

2. Discussion of the Related Art

A solar cell is an element capable of converting light energy into electrical energy. The solar cell may be mainly classified into a silicon-based solar cell, a compound-based solar cell, and an organic-based solar cell depending on a material used. The silicon-based solar cell may be classified into a crystalline silicon (c-Si) solar cell and an amorphous silicon (a-Si) solar cell depending on a phase of a semiconductor. Further, the solar cell may be classified into a bulk type solar cell and a thin film type solar cell depending on a thickness of a semiconductor.

A general operation of the solar cell is as follows. If light coming from the outside is incident on the solar cell, electron-hole pairs are formed inside a silicon layer of the solar cell. Electrons move to an n-type silicon layer and holes move to a p-type silicon layer by an electric field generated in a p-n junction of the electron-hole pairs. Hence, electric power is produced.

When a related art solar cell together uses an amorphous silicon layer and a transparent electrode, photoelectric transformation characteristics of the related art solar cell are reduced because of crystallization of the amorphous silicon layer.

### SUMMARY OF THE INVENTION

In one aspect, there is a solar cell comprising an n-type or p-type amorphous silicon layer, a transparent electrode, and a metal buffer layer between the transparent electrode and the amorphous silicon layer.

The metal buffer layer between the transparent electrode and the amorphous silicon layer may contact each of the transparent electrode and the amorphous silicon layer.

A thickness of the metal buffer layer may be less than a thickness of the transparent electrode.

When a material contained in the metal buffer layer is called a first material and a material contained in the transparent electrode is called a second material, a difference between an electronegativity of the first material and an electronegativity of silicon (Si) of the amorphous silicon layer may be less than a difference between an electronegativity of the second material and the electronegativity of silicon of the amorphous silicon layer.

The electronegativity of the first material may have a value between the electronegativity of the second material and the electronegativity of Si.

A difference between an electronegativity of the first material and an electronegativity of silicon (Si) of the amorphous silicon layer may be less than a difference between the electronegativity of the first material and an electronegativity of the second material.

A thickness of the metal buffer layer may be approximately 0.1 nm to 100.0 nm.

The metal buffer layer may contain at least one of In, Sn, B, Al, Ga, and Zn.

When the transparent electrode contains indium tin oxide (ITO), the metal buffer layer may contain at least one of In and Sn. When the transparent electrode contains zinc oxide, the metal buffer layer may contain at least one of B, Al, Ga, and Zn.

The solar cell may further comprise a grid electrode electrically connected to the transparent electrode.

In another aspect, there is a solar cell comprising a base silicon layer formed of crystalline silicon doped with first impurities, an amorphous silicon layer on the base silicon layer, the amorphous silicon layer being doped with second impurities whose conductive type is different from the first impurities, a transparent electrode, and a metal oxide layer between the transparent electrode and the amorphous silicon layer.

The metal oxide layer between the transparent electrode and the amorphous silicon layer may contact each of the transparent electrode and the amorphous silicon layer.

A thickness of the metal oxide layer may be less than a thickness of the transparent electrode.

A difference between an electronegativity of the metal oxide layer and an electronegativity of the amorphous silicon layer may be less than a difference between an electronegativity of the transparent electrode and the electronegativity of the amorphous silicon layer.

The electronegativity of the metal oxide layer may have a value between the electronegativity of the transparent electrode and the electronegativity of the amorphous silicon layer.

A difference between an electronegativity of the metal oxide layer and an electronegativity of the amorphous silicon layer may be less than a difference between the electronegativity of the metal oxide layer and an electronegativity of the transparent electrode.

When the transparent electrode contains indium tin oxide (ITO), the metal oxide layer may contain at least one of In and Sn. When the transparent electrode contains zinc oxide, the metal oxide layer may contain at least one of B, Al, Ga, and Zn.

The solar cell may further comprise an intrinsic (called i-type) silicon layer between the base silicon layer and the amorphous silicon layer.

In another aspect, there is a solar cell comprising a base silicon layer formed of crystalline silicon doped with first impurities, a first amorphous silicon layer on a surface of the base silicon layer, the first amorphous silicon layer being doped with second impurities whose conductive type is different from the first impurities, a second amorphous silicon layer on another surface of the base silicon layer, the second amorphous silicon layer being doped with third impurities whose conductive type is different from the first impurities, a first metal oxide layer on the first amorphous silicon layer, a second metal oxide layer on the second amorphous silicon layer, a first transparent electrode on the first metal oxide layer, and a second transparent electrode on the second metal oxide layer.

The first metal oxide layer and the second metal oxide layer may be formed of the same material.

A thickness of the first metal oxide layer may be substantially equal to or less than a thickness of the second metal oxide layer.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1 to 3 illustrate an exemplary structure of a solar cell according to an embodiment of the invention;

FIG. 4 illustrates a thickness of a metal buffer layer;

FIGS. 5 and 6 illustrate a material of a metal buffer layer; and

FIGS. 7 to 11 illustrate another exemplary structure of a solar cell according to an embodiment of the invention.

### DETAILED DESCRIPTION OF THE EMBODIMENTS

Reference will now be made in detail to embodiments of the invention, examples of which are illustrated in the accompanying drawings.

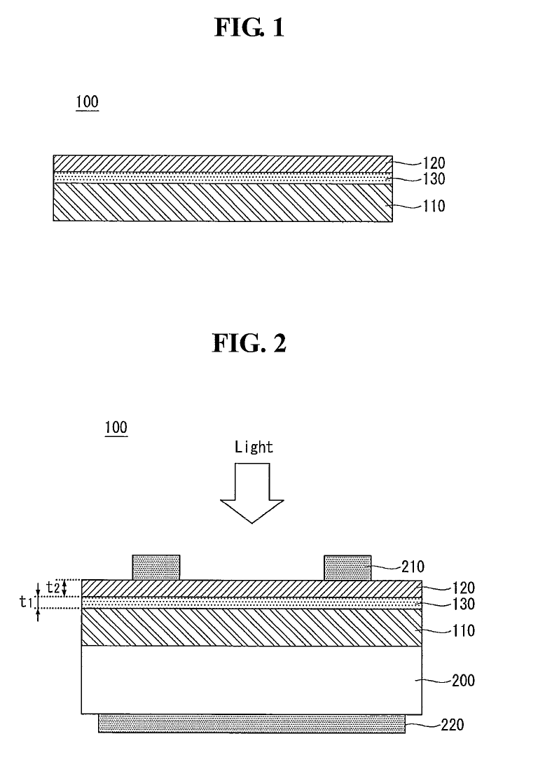

FIGS. 1 to 3 illustrate an exemplary structure of a solar cell according to an embodiment of the invention.

As shown in FIG. 1, a solar cell 100 according to an embodiment of the invention includes an n-type or p-type amorphous silicon layer 110, a transparent electrode 120, and a metal buffer layer 130 between the transparent electrode 120 and the amorphous silicon layer 110. Preferably, the metal buffer layer 130 between the transparent electrode 120 and the amorphous silicon layer 110 may contact each of the transparent electrode 120 and the amorphous silicon layer 110.

Because the metal buffer layer 130 is positioned between the transparent electrode 120 and the amorphous silicon layer 110, the metal buffer layer 130 may prevent crystallization of the amorphous silicon layer 110. The metal buffer layer 130 is described in detail below.

A structure of the solar cell 100 according to the embodiment of the invention may variously vary under the condition that the metal buffer layer 130 is positioned between the transparent electrode 120 and the amorphous silicon layer 110. For example, as shown in FIG. 2, the solar cell 100 may further include a base silicon layer 200 that forms a p-n junction together with the amorphous silicon layer 110.

When the amorphous silicon layer 110 is formed of n-type silicon, the base silicon layer 200 may be formed of p-type silicon. On the contrary, when the amorphous silicon layer 110 is formed of p-type silicon, the base silicon layer 200 may be formed of n-type silicon. In other words, the base silicon layer 200 may be doped with first impurities, and the amorphous silicon layer 110 may be doped with second impurities whose conductive type is different from the first impurities.

A material of the base silicon layer 200 is not particularly limited, except that the base silicon layer 200 and the amorphous silicon layer 110 form the p-n junction. For example, the base silicon layer 200 may be formed of crystalline silicon (c-Si), amorphous silicon (a-Si), or a combination of c-Si and a-Si under the condition that the base silicon layer 200 and the amorphous silicon layer 110 form the p-n junction. The base silicon layer 200 may be a silicon wafer formed of crystalline silicon (c-Si). Otherwise, the base silicon layer 200 may be formed of hydrogenated microcrystalline silicon (mc-Si:H).

When the base silicon layer 200 is formed of crystalline silicon, the solar cell 100 may be called a hetero junction solar cell. The hetero junction solar cell may have higher photoelectric transformation efficiency than a c-Si solar cell formed of only crystalline silicon.

The transparent electrode 120 may be formed of a transparent material with electrical conductivity so as to increase a transmittance of incident light. For example, the transparent electrode 120 may be formed of a material, having high transmittance and high electrical conductivity, selected from the group consisting of indium tin oxide (ITO), tin-based oxide (for example, SnO₂), AgO, ZnO—Ga₂O₃ (or Al₂O₃), fluorine tin oxide (FTO), or a combination thereof, so that the transparent electrode 120 transmits most of incident light and a current flows in the transparent electrode 120. A specific resistance of the transparent electrode 120 may be approximately 10⁻¹¹ Ω·cm to 10⁻² Ω·cm.

The transparent electrode 120 may be electrically connected to the amorphous silicon layer 110. Hence, the transparent electrode 120 may collect one or example, holes) of carriers produced by the incident light to output the holes.

Further, in the solar cell 100 according to the embodiment of the invention, a grid electrode 210 electrically connected to the transparent electrode 120 may be further positioned on the transparent electrode 120.

The solar cell 100 may include a rear electrode 220 positioned in the rear of the base silicon layer 200. The rear electrode 220 may be formed of metal with high electrical conductivity so as to increase a recovery efficiency of electric power produced by the amorphous silicon layer 110 and the base silicon layer 200. Further, the rear electrode 220 electrically connected to the base silicon layer 200 may collect one (for example, electrons) of the carriers produced by the incident light to output the electrons.

In the embodiment, the transparent electrode 120 positioned around a light incident surface may be called a first electrode, and the rear electrode 220 may be called a second electrode. The rear electrode 220 may be formed of substantially transparent material similar to the transparent electrode 120, for example, ITO and ZnO.

In such a structure of the solar cell 100, if light from the outside is incident on the solar cell 100, light energy is converted into electrical energy in a junction surface between the amorphous silicon layer 110 and the base silicon layer 200 forming the p-n junction. Hence, electric power may be produced. The electric power produced in the p-n junction surface may be recovered through the transparent electrode 120 and the rear electrode 220.

Because the metal buffer layer 130 between the amorphous silicon layer 110 and the transparent electrode 120 has a very small thickness t1, the metal buffer layer 130 does not reduce a light transmittance. However, the thickness t1 of the metal buffer layer 130 may be equal to or less than a thickness t2 of the transparent electrode 120, so that the light transmittance is kept at a sufficiently high level.

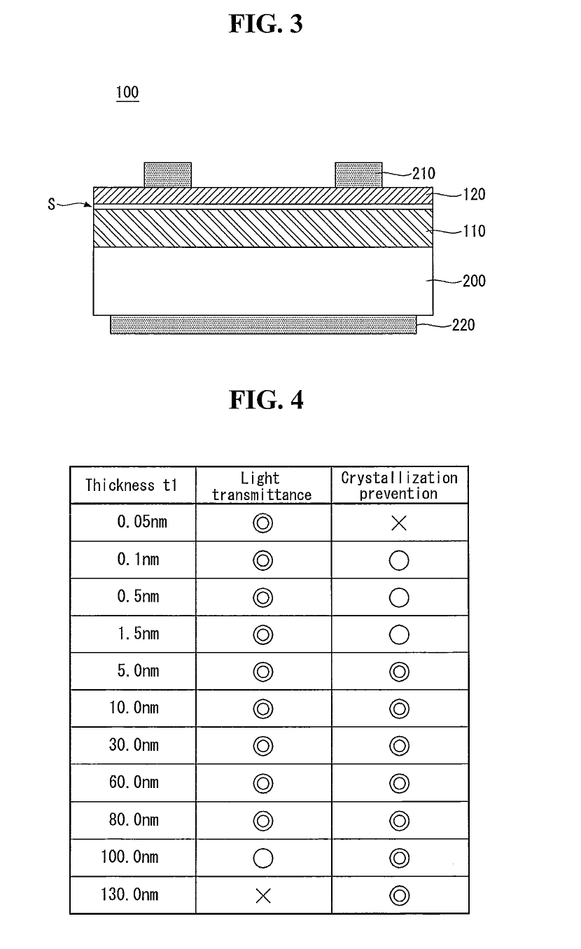

FIG. 3 illustrates an example of omitting the metal buffer layer 130 in the solar cell 100.

As shown in FIG. 3, if the metal buffer layer 130 is omitted in the solar cell 100, the transparent electrode 120 may be formed on the amorphous silicon layer 110. In this case, a sputtering process may be used to form the transparent electrode 120 on the amorphous silicon layer 110. In the sputtering process, when a sputtered target material is deposited on the amorphous silicon layer 110, kinetic energy of sputtering atoms is transferred to the amorphous silicon layer 110. Thus, a phase of the amorphous silicon layer 110 may be partially crystallized in a portion (i.e., an area S) of the amorphous silicon layer 110. As a result, characteristics of the solar cell 100 may be reduced.

There may be an electronegativity difference as another reason of the crystallization of the amorphous silicon layer 110. More specifically, because there is a great difference between electronegativity of a material of the transparent electrode 120 and electronegativity of a material (i.e., silicon) of the amorphous silicon layer 110, the material of the transparent electrode 120 breaks Si—H bonds of the amorphous silicon layer 110 and produces metal hydride (Me-H) bonds or metal hydroxy (Me-OH) bonds in the amorphous silicon layer 110. Hence, a concentration of hydrogen (H) inside the amorphous silicon layer 110 may be reduced, and the crystallization of the amorphous silicon layer 110 may be generated.

On the other hand, in the embodiment of the invention, the metal buffer layer 130 between the amorphous silicon layer 110 and the transparent electrode 120 may prevent kinetic energy of sputtering atoms from being transferred to the amorphous silicon layer 110 in a sputtering process of the transparent electrode 120. Further, the metal buffer layer 130 may prevent metal hydride (Me-H) bonds or metal hydroxy (Me-OH) bonds from being produced in the amorphous silicon layer 110 because of a difference between the electronegativity of the material of the transparent electrode 120 and the electronegativity of silicon of the amorphous silicon layer 110.

A material of the metal buffer layer 130 is not particularly limited, except that metal capable of preventing the crystallization of the amorphous silicon layer 110 is selected. For example, the metal buffer layer 130 may be formed of one or at least two of In, Sn, B, Al, Ga, and Zn in consideration of the manufacturing cost, the electronegativity, etc.

FIG. 4 is a table illustrating a thickness of the metal buffer layer 130. More specifically, FIG. 4 is a table illustrating a light transmittance and crystallization prevention when a thickness t1 of the metal buffer layer 130 changes from 0.05 nm to 130.0 nm. In FIG. 4, X, ∘, and □ in each of the light transmission and crystallization prevention characteristics represent bad, good, and excellent states of the characteristics, respectively.

First, in the light transmission characteristic, when the thickness t1 of the metal buffer layer 130 is approximately 130.0 nm, the light transmission characteristic is in the bad state. In this case, the light transmission may be excessively reduced because of the excessively large thickness t1 of the metal buffer layer 130. Hence, photoelectric transformation efficiency of the solar cell 100 may be reduced because of a reduction in an amount of light reaching the amorphous silicon layer 110.

On the other hand, when the thickness t1 of the metal buffer layer 130 is approximately 0.05 nm to 80.0 nm, the light transmission characteristic is in the excellent state. In this case, the sufficiently high light transmission may be obtained because of the sufficiently small thickness t1 of the metal buffer layer 130. Hence, the photoelectric transformation efficiency of the solar cell 100 may be improved because of a sufficient amount of light reaching the amorphous silicon layer 110.

Although the metal buffer layer 130 is formed of metal, a portion or all of the metal buffer layer 130 may change into metal oxide in a process for forming the transparent electrode 120 (for example, the sputtering process) or a subsequent thermal process. Hence, the light transmission may increase. Accordingly, even if the metal buffer layer 130 formed of metal is positioned between the amorphous silicon layer 110 and the transparent electrode 120, the light transmission may be kept at a sufficiently high level when the thickness t1 of the metal buffer layer 130 is approximately 0.05 nm to 80.0 nm.

Considering that the metal buffer layer 130 changes into metal oxide in the process for forming the transparent electrode 120 or the thermal process, it seems that the metal buffer layer 130 contains metal oxide. In other words, it seems that a metal oxide layer is positioned between the amorphous silicon layer 110 and the transparent electrode 120.

When the thickness t1 of the metal buffer layer 130 is approximately 100.0 nm, the light transmission characteristic is in the good state.

Next, in the crystallization prevention characteristic of the amorphous silicon layer 110, when the thickness t1 of the metal buffer layer 130 is approximately 0.05 nm, the crystallization prevention characteristic is in the bad state. In this case, it is difficult to prevent kinetic energy of sputtering atoms from being transferred to the amorphous silicon layer 110 in the sputtering process of the transparent electrode 120 because of the excessively small thickness t1 of the metal buffer layer 130. Further, it is difficult to prevent metal hydride (Me-H) bonds or metal hydroxy (Me-OH) bonds from being produced in the amorphous silicon layer 110 because of a difference between electronegativity of the material of the transparent electrode 120 and electronegativity of silicon of the amorphous silicon layer 110. As a result, a portion of the amorphous silicon layer 110 may be crystallized.

On the other hand, when the thickness t1 of the metal buffer layer 130 is approximately 5.0 nm to 130.0 nm, the crystallization prevention characteristic is in the excellent state. In this case, kinetic energy of sputtering atoms may be prevented from being transferred to the amorphous silicon layer 110 in the sputtering process of the transparent electrode 120 because of the sufficiently large thickness t1 of the metal buffer layer 130. Further, metal hydride (Me-H) bonds or metal hydroxy (Me-OH) bonds may be prevented from being produced in the amorphous silicon layer 110 because of a difference between electronegativity of the material of the transparent electrode 120 and electronegativity of silicon of the amorphous silicon layer 110. As a result, a portion of the amorphous silicon layer 110 may be prevented from being crystallized.

When the thickness t1 of the metal buffer layer 130 is approximately 0.1 nm to 1.5 nm, the crystallization prevention characteristic is in the good state.

Considering the description of FIG. 4, the thickness t1 of the metal buffer layer 130 may be approximately 0.1 nm to 100.0 nm or 5.0 nm to 80.0 nm.

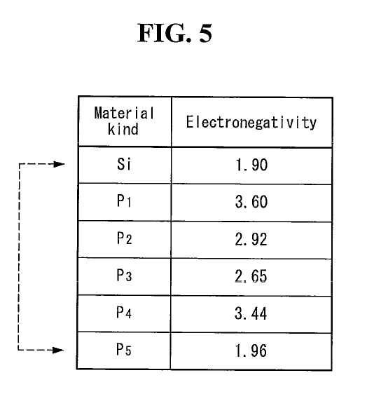

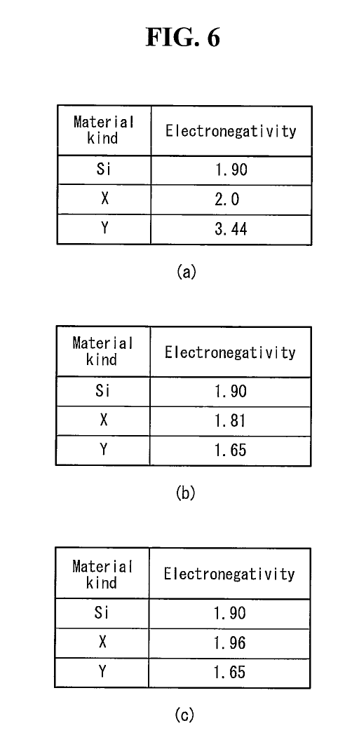

FIGS. 5 and 6 illustrate a material of the metal buffer layer 130.

FIG. 5 is a graph illustrating electronegativity of silicon of the amorphous silicon layer 110 and electronegativity of various materials.

In FIG. 5, electronegativity of silicon is approximately 1.90, electronegativity of a material P1 is approximately 3.60, electronegativity of a material P2 is approximately 2.92, electronegativity of a material P3 is approximately 2.65, electronegativity of a material P4 is approximately 3.44, and electronegativity of a material P5 is approximately 1.96.

As electronegativity of silicon and electronegativity of the material of the metal buffer layer 130 increase, Si—H bonds in the amorphous silicon layer 110 are broken and metal hydride (Me-H) bonds or metal hydroxy (Me-OH) bonds are produced in the amorphous silicon layer 110. Hence, a concentration of hydrogen (H) inside the amorphous silicon layer 110 may be reduced. In this case, the photoelectric transformation efficiency of the solar cell 100 may be reduced because of the crystallization of the amorphous silicon layer 110.

Accordingly, it may be preferable that the metal buffer layer 130 is formed of a material having a relatively small difference between the electronegativity of the material of the metal buffer layer 130 and the electronegativity of Si. As a result, it may be preferable that the metal buffer layer 130 is formed of the material P5, because a difference between electronegativity of the material P5 and the electronegativity of Si is a minimum value among the materials P1 to P5 of FIG. 5.

Further, the material of the metal buffer layer 130 may be selected in consideration of the electronegativity of the transparent electrode 120 and the electronegativity of the amorphous silicon layer 110.

In the embodiment, the material contained in the metal buffer layer 130 is called a first material, and the material contained in the transparent electrode 120 is called a second material.

In this case, a difference between electronegativity of the first material and the electronegativity of Si may be less than a difference between electronegativity of the second material and the electronegativity of Si. In other words, a difference between the electronegativity of the material of the metal buffer layer 130 and the electronegativity of the material (i.e., silicon) of the amorphous silicon layer 110 may be less than a difference between the electronegativity of the material of the transparent electrode 120 and the electronegativity of the material (i.e., silicon) of the amorphous silicon layer 110. It may be preferable that a magnitude of the electronegativity of the first material has a value between the electronegativity of the second material and the electronegativity of Si.

Further, a difference between the electronegativity of the first material and the electronegativity of Si may be less than a difference between the electronegativity of the first material and the electronegativity of the second material.

As shown in (a) of FIG. 6, it is assumed that electronegativity of a first material X contained in the metal buffer layer 130 is approximately 2.0 and electronegativity of a second material Y contained in the transparent electrode 120 is approximately 3.44 when electronegativity of Si is approximately 1.90.

In this case, a difference (i.e., 2.0−1.9=0.1) between the electronegativity of Si and the electronegativity of the first material X is less than a difference (i.e., 3.44−1.90=1.54) between the electronegativity of Si and the electronegativity of the second material Y. Hence, metal hydride (Me-H) bonds or metal hydroxy (Me-OH) bonds may be prevented from being produced in the amorphous silicon layer 110 because of the electronegativity difference.

As shown in (b) of FIG. 6, it is assumed that electronegativity of the first material X contained in the metal buffer layer 130 is approximately 1.81 and electronegativity of the second material Y contained in the transparent electrode 120 is approximately 1.65 when electronegativity of Si is approximately 1.90.

In this case, a difference (i.e., 1.90−1.81=0.09) between the electronegativity of Si and the electronegativity of the first material X is less than a difference (i.e., 1.90−1.65=0.25) between the electronegativity of Si and the electronegativity of the second material Y. Hence, metal hydride (Me-H) bonds or metal hydroxy (Me-OH) bonds may be prevented from being produced in the amorphous silicon layer 110 because of the electronegativity difference.

As shown in (c) of FIG. 6, electronegativity 1.96 of the first material X is not a value between electronegativity 1.65 of the second material Y and electronegativity 1.90 of Si. However, when a difference (i.e., 1.96−1.90=0.06) between the electronegativity of the first material X and the electronegativity of Si is less than a difference (i.e., 1.90−1.65=0.25) between the electronegativity of Si and the electronegativity of the second material Y, metal hydride (Me-H) bonds or metal hydroxy (Me-OH) bonds may be prevented from being produced in the amorphous silicon layer 110 because of the electronegativity difference.

Further, there may be a small difference between the electronegativity of the material of the metal buffer layer 130 and the electronegativity of Si, so as to completely prevent the crystallization of the amorphous silicon layer 110 between the metal buffer layer 130 and the amorphous silicon layer 110. For this, a difference between electronegativity of the first material X and electronegativity of Si may be less than a difference between electronegativity of the first material X and electronegativity of the second material Y. For example, as shown in (a) of FIG. 6, a difference (i.e., 2.0−1.90=0.1) between electronegativity of the first material X and electronegativity of Si is less than a difference (i.e., 3.44−2.0=1.54) between electronegativity of the first material X and electronegativity of the second material Y.

In other words, it may be preferable that the material of the metal buffer layer 130 is selected in consideration of electronegativity of the material of the transparent electrode 120 and electronegativity of Si. More specifically, the material of the metal buffer layer 130 may be a material having electronegativity similar to of Si or a material in which there is a relatively small difference between electronegativity of the material and electronegativity of Si. For example, the material of the metal buffer layer 130 may include at least one of In, Sn, B, Al, Ga, and Zn.

More preferably, when the transparent electrode 120 contains indium tin oxide (ITO) in consideration of electronegativity difference, the metal buffer layer 130 may contain at least one of In and Sn. Otherwise, when the transparent electrode 120 contains zinc oxide (ZnO), the metal buffer layer 130 may contain at least one of B, Al, Ga, and Zn.

Considering that electronegativity of Si is approximately 1.90 and electronegativity of Sn is approximately 1.96, the metal buffer layer 130 may contain Sn.

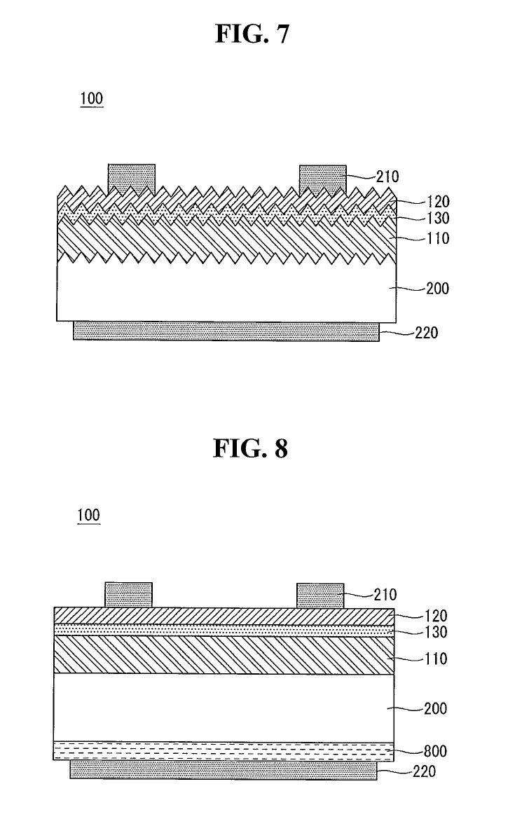

FIGS. 7 to 11 illustrate another exemplary structure of a solar cell according to an embodiment of the invention.

As shown in FIG. 7, a solar cell 100 according to an embodiment of the invention may have a light receiving surface having an uneven pattern. More specifically, the entire surface of a base silicon layer 200 may have an uneven pattern, and thus each of an amorphous silicon layer 110, a metal buffer layer 130, and a transparent electrode 120 formed on the entire surface of the base silicon layer 200 may have an uneven pattern. As above, when the light receiving surface of the solar cell 100 has the uneven pattern, photoelectric transformation efficiency of the solar cell 100 may be improved because of an increase in the size of the light receiving surface.

Although FIG. 7 shows the amorphous silicon layer 110, the transparent electrode 120, the metal buffer layer 130, and the base silicon layer 200 each having the uneven pattern, at least one of the amorphous silicon layer 110, the transparent electrode 120, the metal buffer layer 130, and the base silicon layer 200 may have the uneven pattern.

As shown in FIG. 8, another amorphous silicon layer 800 may be positioned between the base silicon layer 200 and a rear electrode 220. In FIG. 8, the amorphous silicon layer 110 between the metal buffer layer 130 and the base silicon layer 200 is called a first amorphous silicon layer, and the amorphous silicon layer 800 between the base silicon layer 200 and the rear electrode 220 is called a second amorphous silicon layer.

The second amorphous silicon layer 800 may be formed of silicon of the same kind as the base silicon layer 200. For example, when the base silicon layer 200 is formed of p-type silicon, the second amorphous silicon layer 800 may be formed of p-type silicon.

In other words, the base silicon layer 200 may be doped with first impurities, the first amorphous silicon layer 110 on a surface of the base silicon layer 200 may be doped with second impurities whose conductive type is different from the first impurities, and the second amorphous silicon layer 800 on another surface of the base silicon layer 200 may be doped with third impurities whose conductive type is different from the first impurities.

As above, when the solar cell 100 further includes the second amorphous silicon layer 800, an electric field of the silicon layer may be enhanced and the photoelectric transformation efficiency of the solar cell 100 may be improved.

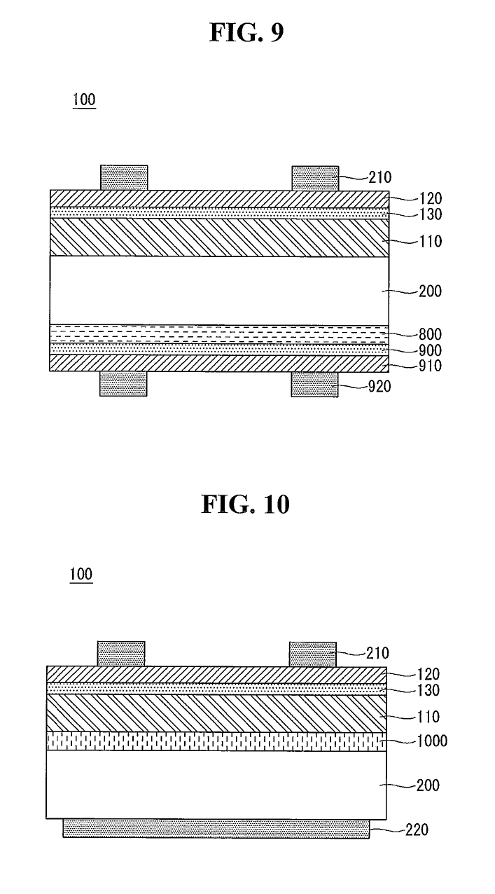

As shown in FIG. 9, the rear electrode 220 may be replaced with another transparent electrode 910. In FIG. 9, the transparent electrode 120 on a front surface of the base silicon layer 200 is called a first transparent electrode, and the transparent electrode 910 replacing the rear electrode 220 is called a second transparent electrode.

As above, when the second transparent electrode 910 is positioned on a rear surface of the base silicon layer 200, another grid electrode 920 electrically connected to the second transparent electrode 910 may be positioned on the second transparent electrode 910.

Further, as shown in FIG. 9, a second amorphous silicon layer 800 may be positioned on the rear surface of the base silicon layer 200. When the second transparent electrode 910 is positioned on the rear surface of the base silicon layer 200, another metal buffer layer 900 may be positioned between the second amorphous silicon layer 800 and the second transparent electrode 910.

The metal buffer layer 900 may be formed of the same material as the metal buffer layer 130 between the first amorphous silicon layer 110 and the first transparent electrode 120. In FIG. 9, the metal buffer layer 130 between the first amorphous silicon layer 110 and the first transparent electrode 120 is called a first metal buffer layer, and the metal buffer layer 900 is called a second metal buffer layer.

If a material of the first transparent electrode 120 is different from a material of the second transparent electrode 910, a material of the first metal buffer layer 130 may be different from a material of the second metal buffer layer 900. In other words, the material of the first metal buffer layer 130 may be selected in consideration of electronegativity of the first transparent electrode 120, and the material of the second metal buffer layer 900 may be selected in consideration of electronegativity of the second transparent electrode 910.

Because the first metal buffer layer 130 is positioned around a light incident surface, it may be preferable that the first metal buffer layer 130 has a high light transmittance. On the other hand, because the second metal buffer layer 900 is positioned opposite the light incident surface, the second metal buffer layer 900 does not need to have a high light transmittance. Considering this, the light transmittance of the first metal buffer layer 130 may increase by making the first metal buffer layer 130 thin, and the crystallization of the second amorphous silicon layer 800 may be completely prevented by making the second metal buffer layer 900 relatively thick. Accordingly, a thickness of the first metal buffer layer 130 may be substantially equal to or less than a thickness of the second metal buffer layer 900.

Next, as shown in FIG. 10, an intrinsic (called i-type) silicon layer 1000 may be further positioned between the amorphous silicon layer 110 and the base silicon layer 200. Although it is not shown, an intrinsic (called i-type) silicon layer may be further positioned between the second amorphous silicon layer 800 and the base silicon layer 200 when the second amorphous silicon layer 800 is positioned as shown in FIGS. 8 and 9. The i-type silicon layer may improve interface characteristics between the amorphous silicon layer 110 and the base silicon layer 200.

Further, although it is not shown, i-type silicon layers may be respectively positioned between the base silicon layer 200 and the first amorphous silicon layer 110 and between the base silicon layer 200 and the second amorphous silicon layer 800 when the first amorphous silicon layer 110 and the second amorphous silicon layer 800 are positioned as shown in FIGS. 8 and 9.

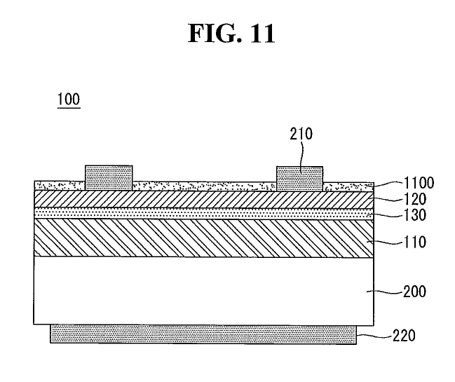

Further, as shown in FIG. 11, an anti-reflective layer 1100 may be positioned on the transparent electrode 120. The anti-reflective layer 1100 may suppress reflection of light coming from the outside to thereby reduce a light reflectance of the solar cell 100. Hence, the photoelectric transformation efficiency of the solar cell 100 may be improved.

In embodiments of the invention, reference to front or back, with respect to electrode, a surface of the substrate, or others is not limiting. For example, such a reference is for convenience of description since front or back is easily understood as examples of first or second of the electrode, the surface of the substrate or others.

While this invention has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
an n-type or p-type amorphous silicon layer;
a transparent electrode; and
a metal buffer layer between the transparent electrode and the amorphous silicon layer.

2. The solar cell of claim 1, wherein the metal buffer layer between the transparent electrode and the amorphous silicon layer contacts each of the transparent electrode and the amorphous silicon layer.

3. The solar cell of claim 1, wherein a thickness of the metal buffer layer is less than a thickness of the transparent electrode.

4. The solar cell of claim 1, wherein when a material contained in the metal buffer layer is called a first material and a material contained in the transparent electrode is called a second material, a difference between an electronegativity of the first material and an electronegativity of silicon (Si) of the amorphous silicon layer is less than a difference between an electronegativity of the second material and the electronegativity of silicon of the amorphous silicon layer.

5. The solar cell of claim 4, wherein the electronegativity of the first material has a value between the electronegativity of the second material and the electronegativity of Si.

6. The solar cell of claim 1, wherein when a material contained in the metal buffer layer is called a first material and a material contained in the transparent electrode is called a second material, a difference between an electronegativity of the first material and an electronegativity of silicon (Si) of the amorphous silicon layer is less than a difference between the electronegativity of the first material and an electronegativity of the second material.

7. The solar cell of claim 1, wherein a thickness of the metal buffer layer is approximately 0.1 nm to 100.0 nm.

8. The solar cell of claim 1, wherein the metal buffer layer contains at least one of In, Sn, B, Al, Ga, and Zn.

9. The solar cell of claim 1, wherein when the transparent electrode contains indium tin oxide (ITO), the metal buffer layer contains at least one of In and Sn.

10. The solar cell of claim 1, wherein when the transparent electrode contains zinc oxide, the metal buffer layer contains at least one of B, Al, Ga, and Zn.

11. The solar cell of claim 1, further comprising a grid electrode electrically connected to the transparent electrode.

12. The solar cell of claim 1, wherein the metal buffer layer is a metal oxide layer.

13. A solar cell comprising:
a base silicon layer formed of crystalline silicon doped with first impurities;
an amorphous silicon layer on the base silicon layer, the amorphous silicon layer being doped with second impurities whose conductive type is different from the first impurities;
a transparent electrode; and
a metal oxide layer between the transparent electrode and the amorphous silicon layer.

14. The solar cell of claim 13, wherein the metal oxide layer between the transparent electrode and the amorphous silicon layer contacts each of the transparent electrode and the amorphous silicon layer.

15. The solar cell of claim 13, wherein a thickness of the metal oxide layer is less than a thickness of the transparent electrode.

16. The solar cell of claim 13, wherein a difference between an electronegativity of the metal oxide layer and an electronegativity of the amorphous silicon layer is less than a difference between an electronegativity of the transparent electrode and the electronegativity of the amorphous silicon layer.

17. The solar cell of claim 16, wherein the electronegativity of the metal oxide layer has a value between the electronegativity of the transparent electrode and the electronegativity of the amorphous silicon layer.

18. The solar cell of claim 13, wherein a difference between an electronegativity of the metal oxide layer and an electronegativity of the amorphous silicon layer is less than a difference between the electronegativity of the metal oxide layer and an electronegativity of the transparent electrode.

19. The solar cell of claim 13, wherein when the transparent electrode contains indium tin oxide (ITO), the metal oxide layer contains at least one of In and Sn.

20. The solar cell of claim 13, wherein when the transparent electrode contains zinc oxide, the metal oxide layer contains at least one of B, Al, Ga, and Zn.

21. The solar cell of claim 13, further comprising an intrinsic (called i-type) silicon layer between the base silicon layer and the amorphous silicon layer.

22. A solar cell comprising:
a base silicon layer formed of crystalline silicon doped with first impurities;
a first amorphous silicon layer on a surface of the base silicon layer, the first amorphous silicon layer being doped with second impurities whose conductive type is different from the first impurities;
a second amorphous silicon layer on another surface of the base silicon layer, the second amorphous silicon layer being doped with third impurities whose conductive type is different from the first impurities;
a first metal oxide layer on the first amorphous silicon layer;
a second metal oxide layer on the second amorphous silicon layer;
a first transparent electrode on the first metal oxide layer; and
a second transparent electrode on the second metal oxide layer.

23. The solar cell of claim 22, wherein the first metal oxide layer and the second metal oxide layer are formed of the same material.

24. The solar cell of claim 22, wherein a thickness of the first metal oxide layer is substantially equal to or less than a thickness of the second metal oxide layer.
